(19) United States
(12) Patent Application Publication
(10) Pub. No.: US 2026/0173611 A1
(43) Pub. Date: Jun. 18, 2026

(54) DISPLAY APPARATUS

(71) Applicant: SAMSUNG ELECTRONICS CO., LTD., Suwon-si (KR)

(72) Inventors: Dohoon KIM, Yokohama-shi (JP); Eiji HASEGAWA, Yokohama-shi (JP); Kazuyuki ISHIKAWA, Yokohama-shi (JP)

(73) Assignee: SAMSUNG ELECTRONICS CO., LTD., Suwon-si (KR)

(21) Appl. No.: 19/219,389

(22) Filed: May 27, 2025

Related U.S. Application Data
(63) Continuation of application No. PCT/KR2025/006777, filed on May 19, 2025.

(30) Foreign Application Priority Data
Dec. 18, 2024 (JP) 2024-221359

(51) Int. Cl. H10H 29/37; H10H 29/856

(52) U.S. Cl. CPC H10H 29/37; H10H 29/856

(57) ABSTRACT

A refrigerator and a controlling method thereof will be provided. The refrigerator includes a camera, memory stored with at least one instruction, and one or more processors configured to execute the at least one instruction, control the camera to capture an object based on the object being entered in or taken from the refrigerator, provide, based on obtaining a capture image about the object entered in or taken from the refrigerator, a guide for obtaining an additional image based on the obtained capture image, obtain, based on detecting a signal for capturing the object corresponding to the provided guide, an additional image through the camera, and store the capture image and the additional image as data on the object being entered or taken.

### CROSS-REFERENCE TO RELATED APPLICATIONS

This application is a continuation of International Application No. PCT/KR 2025/006777 designating the United States, filed on May 19, 2025, in the Korean Intellectual Property Receiving Office, which claims priority to Japanese Patent Application No. 2024-221359, filed on Dec. 18, 2024, in the Japan Patent Office, the disclosures of which are incorporated by reference herein in their entireties.

### BACKGROUND

### 1. Field

The present disclosure relates to a display apparatus.

### 2. Description of Related Art

A display apparatus, such as a mirror display or a decoration display, may display an image by, for example, emitting light emitted from a plurality of light-emitting elements through a plurality of apertures disposed in an aperture substrate.

For example, the mirror display may include a display substrate on which the plurality of light-emitting elements are arranged, and a transparent substrate on which a reflective layer is disposed, and at each position of the reflective layer corresponding to the plurality of light-emitting elements, an aperture may be disposed for transmitting light emitted from the light-emitting elements. Based on this configuration, the display apparatus may implement a display function for displaying an image by emitting light and a mirror function for illuminating a surrounding object by reflecting light.

In a reflective layer of a mirror display, an aperture may be disposed only at a position corresponding to a light-emitting element, and an image may be displayed in a region where the aperture is disposed. Therefore, in the reflective layer of the mirror display, a display region where the image is displayed and a non-display region disposed around the display region and where no image is displayed may have different reflexivity depending on a presence or an absence of the aperture. As a result, for example, if a user views the mirror display from a front, there is a problem that a difference occurs in visibility (or perceptibility) between the display region and the non-display region, which may cause a deterioration in display quality.

In addition, the problem of the difference in visibility caused by the presence or absence of the aperture may be present not only in the mirror display but also in other types of a display such as a decoration display having the same configuration as the mirror display.

### SUMMARY

Provided is a display apparatus capable of suppressing the difference in visibility between the display region and the non-display region in the display apparatus that displays an image by emitting light emitted from the plurality of light-emitting elements through the plurality of apertures disposed in an aperture substrate.

One or more example embodiments of the present disclosure provide a display apparatus having improved display quality by suppressing a difference in visibility between a display region and a non-display region of the display apparatus.

According to an aspect of an example embodiment of the present disclosure, provided is a display apparatus including: a display substrate on which a plurality of light-emitting elements are arranged; and an aperture substrate facing the display substrate, and including: a display region in which at least one aperture is disposed at each position corresponding to each of the plurality of light-emitting elements and a light emitted from each of the plurality of light-emitting elements is transmitted through the at least one aperture; and a non-display region which is different from the display region and in which at least one dummy aperture is disposed.

The aperture substrate includes a transparent substrate, and a reflective layer which is disposed on the transparent substrate and in which the at least one aperture is disposed.

The aperture substrate is larger than the display substrate, the at least one dummy aperture is disposed in a non-overlapping region of the aperture substrate that does not overlap with the display substrate, and the aperture substrate further includes a light-shielding layer disposed on a surface of the display substrate in the non-overlapping region.

The display substrate includes a plurality of display substrates, and the plurality of display substrates are joined to one aperture substrate.

In the non-display region, a dummy light-emitting element is disposed at a position corresponding to the at least one dummy aperture.

The display substrate includes a circuit board, and the plurality of light-emitting elements disposed on the circuit board.

The display substrate further includes a light-shielding layer that is disposed in a region on the circuit board other than a region in which a light-emitting element is disposed on the circuit board.

The light-shielding layer included in the display substrate covers a side surface of the light-emitting element.

The display apparatus further includes a transparent adhesive layer disposed between the display substrate and the aperture substrate.

The plurality of light-emitting elements include a micro light-emitting diode (LED).

A size of an aperture of the at least one aperture is the same as or larger than a size of a light-emitting element of the plurality of light-emitting elements.

In the display region, one aperture is disposed to correspond to one light-emitting element.

In the display region, one aperture is disposed to correspond to a predetermined number of light-emitting elements among the plurality of light-emitting elements.

The plurality of light-emitting elements include a blue light-emitting element, a green light-emitting element, and a red light-emitting element.

The plurality of light-emitting elements include light-emitting elements that emit a light of a specific wavelength, and the display apparatus further includes a color conversion layer that converts the light of the specific wavelength into a light of a different wavelength.

According to the present disclosure, a display apparatus that displays an image by emitting light emitted from the plurality of light-emitting elements through the aperture disposed in the aperture substrate may suppress a difference in the visible method between the display region and the non-display region.

### BRIEF DESCRIPTION OF THE DRAWINGS

Example embodiments of the present disclosure will be more clearly understood from the following detailed description taken in conjunction with the accompanying drawings.

FIG. 1 is a plan view schematically illustrating a display apparatus according to an example embodiment.

FIG. 2 is a cross-sectional view taken along line II-II′ of FIG. 1.

FIGS. 3A-3E are diagrams for describing a manufacturing method of a display apparatus according to an example embodiment.

FIG. 4 is a diagram for describing a functional effect of a display apparatus according to an example embodiment.

FIG. 5 is a diagram showing a general display apparatus as a comparative example.

FIG. 6 is a cross-sectional view illustrating a display apparatus according to Modified Example 1.

FIG. 7 is a cross-sectional view illustrating a display apparatus according to Modified Example 2.

FIG. 8 is a schematic diagram illustrating a display apparatus according to Modified Example 3.

FIG. 9 is a schematic diagram illustrating a display apparatus according to Modified Example 4.

### DETAILED DESCRIPTION

Hereinafter, one or more embodiments of the present disclosure are described in detail with reference to the drawings. In the drawings shown below, the same reference numerals refer to the same components, and the size of each component in the drawings is exaggerated for clarity and convenience of description. Meanwhile, an embodiment(s) described below is merely an example(s), and various modifications are possible from the embodiment(s). In addition, one of ordinary skill would understand that aspects of some embodiments may be combined together or implemented alone.

In the following description, if a component is referred to as being “on” or “above” another component, the component may be directly “on” another component in contact or “above” another component without contact. Similarly, if a component is referred to as being “beneath” or “below” another component, the component may be directly “beneath” another component in contact or “below” another component without contact.

A term of a singular number may include its plural number unless explicitly indicated otherwise in the context. In addition, if a component is described as “including,” “comprising,” or “having” another component, it does not exclude a case where the corresponding component includes other components unless otherwise specifically stated, but rather indicates that the corresponding component may further include other components.

For steps included in a method, if an order is explicitly described, or if there is no description to the contrary, the steps may be executed in an appropriate order. The execution of the steps is not necessarily limited to the order in which the steps are described. Any use of examples or exemplary terms is intended merely to describe the spirit of the present disclosure, and the scope of the present disclosure is not limited by the examples or exemplary terms unless otherwise defined in the claims.

Hereinafter, a display apparatus according to various example embodiment of the present disclosure is described with reference to the drawings. In addition, the following description describes an example in which the display apparatus in the present disclosure is a mirror display having a display function for displaying an image by emitting light and a mirror function for illuminating a surrounding object (e.g., object that is before one side of the display apparatus) by reflecting light. However, the present disclosure is not limited to this example and may apply to other types of a display.

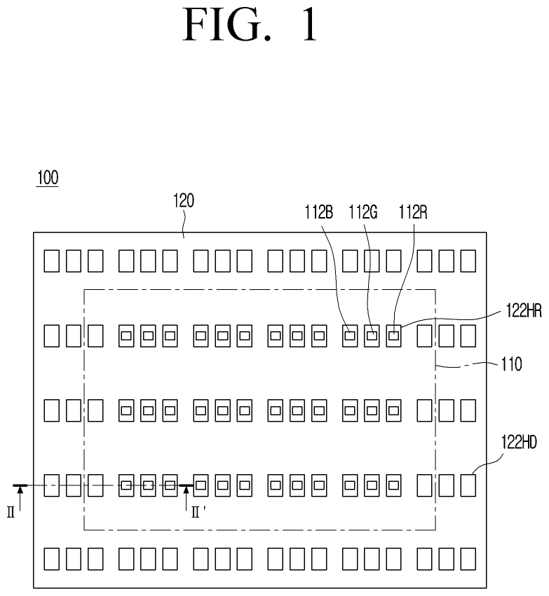

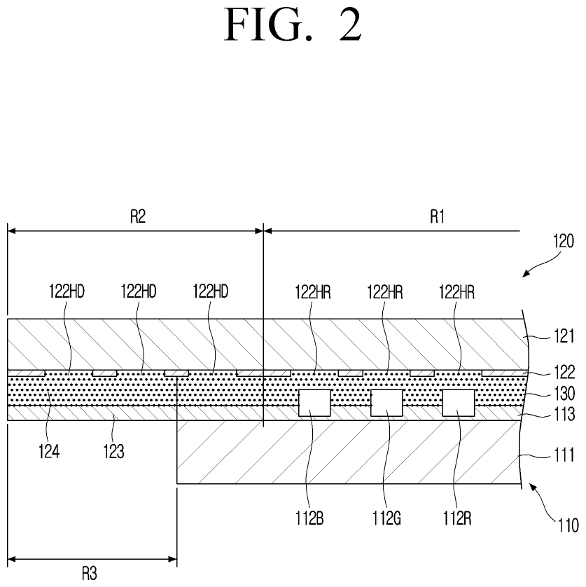

FIG. 1 is a plan view schematically illustrating a display apparatus according to an example embodiment; and FIG. 2 is a cross-sectional view taken along line II-II′ of FIG. 1.

As shown in FIGS. 1 and 2, a display apparatus 100 according to an example embodiment may include a display substrate 110 on which a plurality of light-emitting elements 112B, 112G, and 112R (or collectively 112) are arranged, and an aperture substrate 120, wherein an aperture 122HD or 122HR (or collectively 122H) is disposed on a front surface of the aperture substrate 120. For example, the plurality of light-emitting elements 112 may be regularly arranged on the display substrate 110. The aperture substrate 120 may refer to a substrate in which one or more apertures 122H are disposed. Hereinafter, for illustrative purposes, an example in which the aperture substrate 120 is implemented as a reflective substrate 120 including a reflective layer is described; however, the present disclosure is not limited thereto. The reflective substrate 120 may be larger than the display substrate 110, and the display substrate 110 and the reflective substrate 120 may be joined to each other through a transparent adhesive layer 130.

### Display Substrate 110

The display substrate 110 may include the plurality of light-emitting elements 112 mounted on a circuit board 111. A first light-shielding layer 113 that absorbs a portion of light emitted from the light-emitting elements 112 may be disposed in a region on the circuit board 111 other than a region where the light-emitting element 112 is disposed on the circuit board 111.

The circuit board 111 may include a thin film transistor (TFT) substrate on which a thin film transistor (TFT), a wiring layer (not shown), or the like is disposed to control operations of the plurality of light-emitting elements 112.

The light-emitting element 112 may include a blue light-emitting element 112B that emits blue light, a green light-emitting element 112G that emits green light, and a red light-emitting element 112R that emits red light, and display a color image. However, this is merely an example and the light-emitting may emit light of a color other than red, green, and blue, e.g., yellow light. The light-emitting elements 112B, 112G, and 112R may include micro light-emitting diodes (LEDs) each having a chip size of 100 μm or less, and three light-emitting elements 112B, 112G, and 112R adjacent to each other may constitute one pixel. The three light-emitting elements 112B, 112G, and 112R may be disposed to be adjacent to each other while having a gap smaller than a pixel size and a pixel pitch.

The first light-shielding layer 113 may include, for example but not limited to, a black anisotropic conducting film (ACF). The first light-shielding layer 113 may mechanically and electrically connect the circuit board 111 to the light-emitting element 112, and absorb light emitted from the light-emitting element 112. The light-emitting element 112 may be embedded in the first light-shielding layer 113, and the first light-shielding layer 113 may cover a side surface of the light-emitting element 112.

### Reflective Substrate 120

The reflective substrate 120 may include a reflective layer 122 disposed on a transparent substrate 121. The transparent substrate 121 may include a transparent glass substrate, and the reflective layer 122 may include, for example but not limited to, an alloy of aluminum and neodymium. The reflective layer 122 may be disposed on a rear surface of the transparent substrate 121 and function as a mirror surface that reflects light incident from one side (e.g., front) of the display apparatus 100 to illuminate a surrounding object (e.g., object that is before one side of the display apparatus 100). For example, a front surface of the transparent substrate 121, which is opposite to the rear surface on which the reflective layer 122 is disposed, may serve as the mirror surface.

The reflective substrate 120 may have a display region R1 corresponding to a region in which the light-emitting elements 112 of the display substrate 110 are arranged, and a non-display region R2 disposed outside the display region R1. In the display region R1, an aperture 122HR may be disposed at each position corresponding to each of the plurality of light-emitting elements 112 and transmit light emitted from each of the light-emitting elements 112 therethrough. In the non-display region R2, a dummy aperture 122HD may be disposed to match reflectivity between the display region R1 and the non-display region R2. The apertures 122HR and 122HD may have the same shape and the same size. The apertures 122HR and 122HD may each have a rectangular shape for example, and each size of the apertures 122HR and 122HD may be slightly larger than the chip size of the light-emitting element 112. For example, each size of the apertures 122HR and 122HD may be larger than a size of a front surface of the light-emitting element 112.

A second light-shielding layer 123 may be disposed in a non-overlapping region R3 of the reflective substrate 120, which does not overlap with the display substrate 110. The second light-shielding layer 123 may be joined to the non-overlapping region R3 of the reflective substrate 120 through a transparent adhesive layer 124. The second light-shielding layer 123 may prevent an opposite side of the reflective substrate 120 from being viewed through the dummy aperture 122HD.

The second light-shielding layer 123 may include the same material (or the black anisotropic conductive film) as the first light-shielding layer 113. Alternatively, the second light-shielding layer 123 may include a different material (e.g., black matrix material) from that of the first light-shielding layer 113. If the second light-shielding layer 123 includes the material different from that of the first light-shielding layer 113, a material having a color tone or reflectivity similar to that of the first light-shielding layer 113 may be used as the material of the second light-shielding layer 123. The transparent adhesive layer 124 may include the same material as that of the transparent adhesive layer 130.

### Transparent Adhesive Layer 130

The transparent adhesive layer 130 may be disposed between the display substrate 110 and the reflective substrate 120, and the display substrate 110 and the reflective substrate 120 may be joined to each other. The transparent adhesive layer 130 may include, for example but not limited to, an optical clear resin (OCR).

According to the display apparatus 100 in an example embodiment, the display function for displaying a desired image may be implemented by emitting light emitted from the light-emitting element 112 through the aperture 122HR disposed in the display region R1 of the reflective substrate 120. On the other hand, the mirror function for illuminating the surrounding object may be implemented by reflecting light incident from the front to the reflective layer 122 of the reflective substrate 120.

In more detail, according to the display apparatus 100 in an example embodiment, high-luminance light emitted from the light-emitting element 122 may be emitted to an outside through the aperture 122HR, and accordingly, there is no attenuation of light, and the display function of high display brightness may be implemented. On the other hand, the light-emitting element 112 having a small size may be used to minimize a size of the aperture 122 HR, and to maximize an area of the reflective layer 122 and implement the mirror function of high reflectivity.

In addition, according to the display apparatus 100 in an example embodiment, the first light-shielding layer 113 that absorbs a portion of light emitted from the light-emitting element 112 may be disposed, thereby preventing a portion of light emitted from a specific light-emitting element 112 from being emitted through an aperture 122HR other than a corresponding aperture 122HR, and improving a quality of a displayed image. The first light-shielding layer 113 may absorb light emitted from the light-emitting element 112 and reflected from a surface of the transparent substrate 121 or light emitted from a side surface of the light-emitting element 112.

In addition, an area ratio of the aperture 122HR and/or the aperture 122HD to a surface (e.g., front surface) of the reflective substrate 120 may be about 10%, and an area ratio of the reflective layer 122 may be about 90%. Based on this configuration, a mirror performance of 83% or more reflectivity according to Japanese industrial standards (JIS) may be implemented.

### Method for Manufacturing Display Apparatus 100

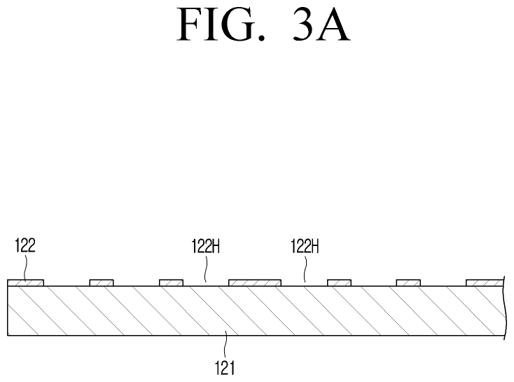

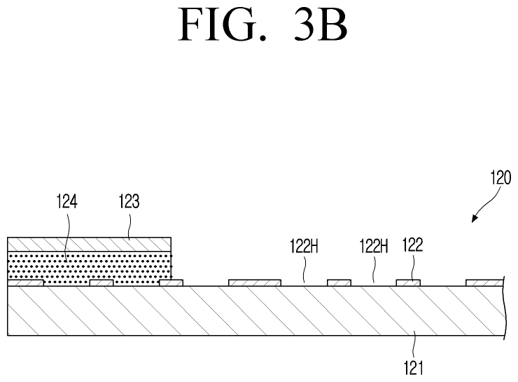

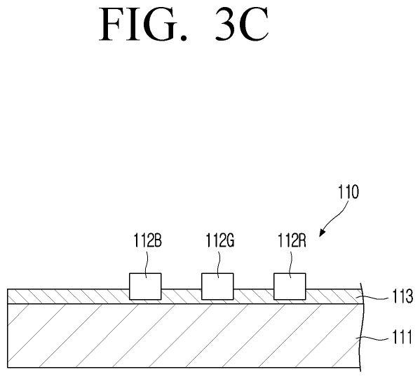

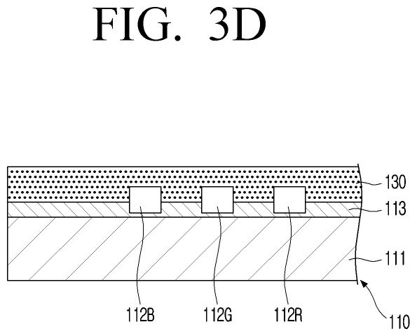

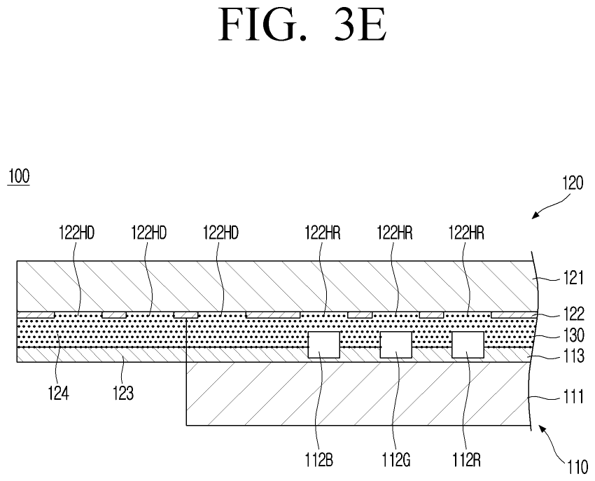

A method for manufacturing a display apparatus (e.g., 100 in FIG. 1) according to an example embodiment is described with reference to FIGS. 3A to 3E.

First, a metal film including, for example, the alloy of aluminum and neodymium may be disposed on the transparent substrate 121, and a portion of the metal film may then be removed using a known photolithography process, thereby forming the reflective layer 122, in which the aperture 122H is disposed, on the transparent substrate 121 (see FIG. 3A).

Next, the second light-shielding layer 123 on the transparent adhesive layer 124 may be disposed at an edge of the transparent substrate 121 where the reflective layer 122, in which the aperture 122H is disposed, is disposed, thereby providing the reflective substrate 120 (see FIG. 3B).

Next, the black anisotropic conducting film may be disposed on the circuit board 111, and the light-emitting element 112 may be embedded in the anisotropic conducting film, thereby providing the display substrate 110 including the light-emitting element 112 and the first light-shielding layer 113 (see FIG. 3C).

Next, the transparent adhesive layer 130 may be coated on top of the display substrate 110 (see FIG. 3D). In addition, the reflective substrate 120 may be attached to the transparent adhesive layer 130 on the display substrate 110 such that the reflective layer 122 of the reflective substrate 120 faces the display substrate 110, thereby providing the display apparatus 100 (see FIG. 3E).

A material(s) of each member included in the display apparatus 100 is not limited to the material(s) described above, and may use various materials. For example, the transparent substrate 121 may be a transparent resin substrate, and the reflective layer 122 may include, for example but not limited to, any metal such as silver, aluminum, a silver alloy, or an aluminum alloy. In addition, the transparent adhesive layer 130 may include, for example but not limited to, an optical clear adhesive (OCA). In addition, the first light-shielding layer 113 is not limited to the black anisotropic conducting film, and may include, for example but not limited to, a black matrix material, or the like. If the first light-shielding layer 113 includes the black matrix material, the light-emitting element 112 may be mounted on the circuit board 111 by a known bonding technique such as soldering. In addition, the first light-shielding layer 113 113 is not limited to black in color, and may use any color that may absorb light.

### Functional Effect of Display Apparatus 100

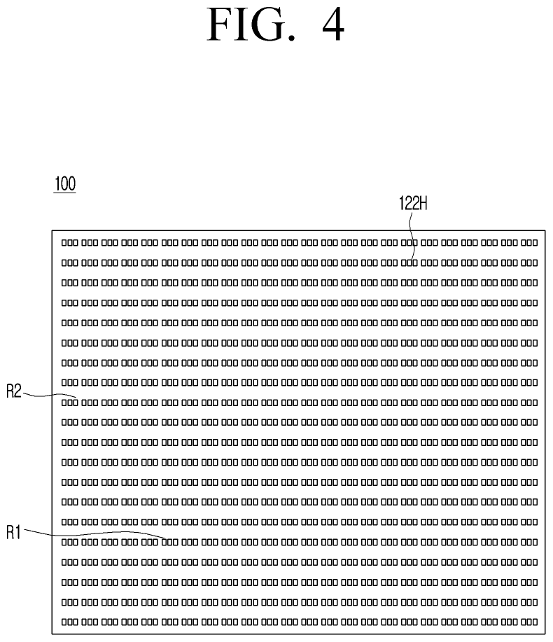

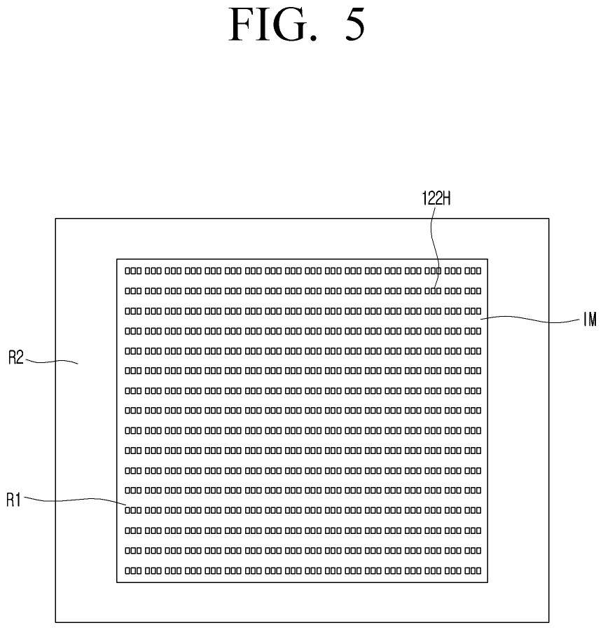

A functional effect of a display apparatus according to an example embodiment is described with reference to FIGS. 4 and 5. FIG. 4 is a diagram for describing a functional effect of a display apparatus (e.g., 100 in FIG. 1) according to an example embodiment. FIG. 5 is a diagram showing a general display apparatus in which an aperture is disposed only in the display region R1 as a comparative example.

As shown in FIG. 5, in the general display apparatus according to the comparative example, the aperture 122H may be disposed only in the display region R1 of the reflective substrate where the image is displayed, and no aperture may be disposed in the non-display region R2 outside the display region R1. Therefore, in the general display apparatus, the reflectivity of the non-display region R2 where no aperture is disposed may become higher than the reflectivity of the display region R1 where the aperture is disposed, and a user may perceive brightness of the non-display region R2 to be stronger than that of the display region R1. Therefore, when the user views the general display apparatus from the front, an image IM displayed on the display substrate, which is joined to a rear surface of the reflective substrate, may be viewed or perceived by the user due to a difference in the reflectivity between the display region R1 and the non-display region R2.

In contrast, as shown in FIG. 4, in the display apparatus 100 according to an example embodiment, the aperture 122H may be disposed on a front surface of the reflective substrate including the display region R1 and the non-display region R2. Therefore, in the display apparatus 100 according to an example embodiment, the reflectivity of the non-display region R2 may become substantially the same as the reflectivity of the display region R1, and the user may not perceive a difference in brightness between the display region R1 and the non-display region R2. Accordingly, if the user views the display apparatus 100 according to an example embodiment from the front, an image displayed on the display substrate 110, which is joined to the rear surface of the reflective substrate 120, may not be viewed or perceived by the user.

As described above, according to the display apparatus 100 in an example embodiment, a difference in visibility (or perceptibility) between the display region R1 and the non-display region R2 may be suppressed, and a display quality of the display apparatus 100 is improved.

In addition, according to the display apparatus 100 in an example embodiment, the second light-shielding layer 123 may be disposed on a rear side of the dummy aperture 122HD disposed in the non-display region R2, thereby preventing an object disposed behind the reflective substrate 120 from being viewed through the dummy aperture 122HD. In addition, a configuration of the display region R1 and a configuration of the non-display region R2 may become close to each other, and the difference in visibility between the display region R1 and the non-display region R2 may further be suppressed.

### MODIFIED EXAMPLES

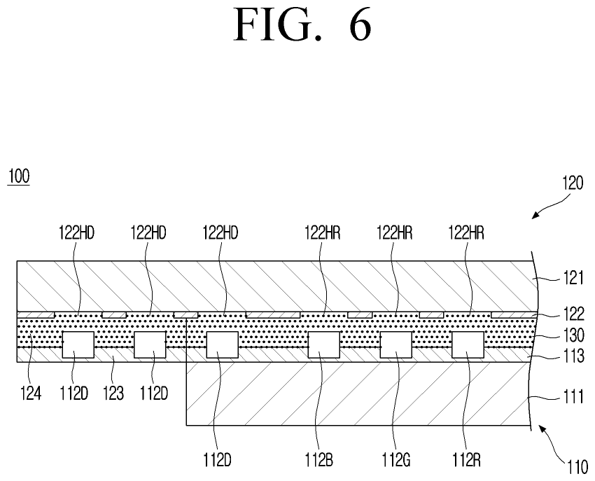

Hereinafter, modified examples of the display apparatus 100 according to example embodiments are described with reference to FIGS. 6 to 9.

### Modified Example 1

FIG. 6 is a cross-sectional view illustrating the display apparatus 100 according to Modified Example 1. As shown in FIG. 6, in the display apparatus 100 according to Modified Example 1, a dummy light-emitting element 122D may be disposed at a position corresponding to the dummy aperture 122HD.

Based on this configuration, the configuration of the display region R1 and the configuration of the non-display region R2 may become closer to each other, and the difference in visibility between the display region R1 and the non-display region R2 may further be suppressed.

### Modified Example 2

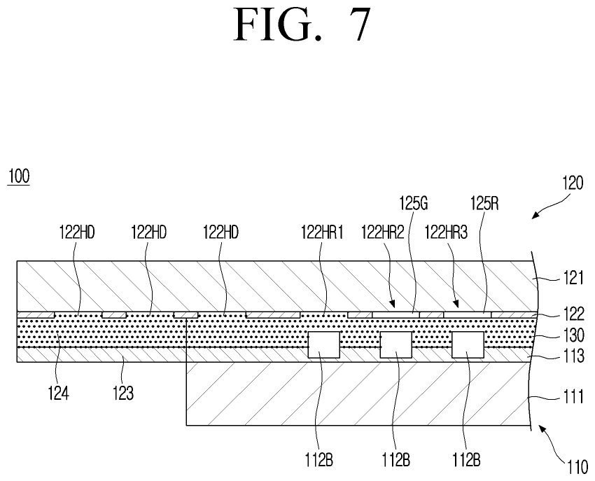

FIG. 7 is a cross-sectional view illustrating the display apparatus 100 according to Modified Example 2. As shown in FIG. 7, in the display apparatus 100 according to Modified Example 2, the plurality of blue light-emitting elements 112B may be mounted on the circuit board 111. In addition, the reflective substrate 120 may have the reflective layer 122 including apertures 122HR1, 122HR2, and 122HR3 disposed at positions corresponding to the blue light-emitting elements 112B. Color conversion layers 125G and 125R may be disposed in two of the three apertures 122HR1, 122HR2, and 122HR3. The color conversion layers 125G and 125R may include the green conversion layer 125G, which includes color conversion material that converts the blue light into the green light, and the red conversion layer 125R, which includes a color conversion material that converts blue light into red light. The color conversion material may include, for example but not limited to, a fluorescent substance or a quantum dot.

Based on this configuration, the color image may be implemented using only the blue light-emitting element 112B. In addition, the first light-shielding layer 113 may be disposed on the circuit board 111, thereby preventing a portion of light emitted from a specific light-emitting element 112B from reaching the aperture 122H other than a corresponding aperture 122H.

Therefore, in the display apparatus 100 according to the modified example, for example, if only a blue image is displayed, the green light or the red light may be prevented from being mixed with the blue light and emitted to the outside, thereby displaying a high-quality blue image.

In addition, the light-emitting element according to this modified example is not limited to the blue light-emitting element, and may use a light-emitting element that emits light of a specific wavelength, such as white light or ultraviolet light. The color conversion material included in the color conversion layer may be changed depending on light emitted from the light-emitting element.

### Modified Example 3

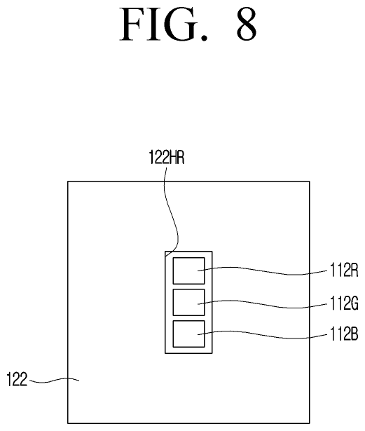

FIG. 8 is a diagram for describing a schematic configuration of the display apparatus according to Modified Example 3. As shown in FIG. 8, in the display apparatus 100 according to Modified Example 3, one aperture 122HR may be disposed corresponding to three light-emitting elements 112R, 112G, and 112B of the red light-emitting element, the green light-emitting element, and the blue light-emitting element. Based on this configuration, an area ratio of the aperture 122H to the reflective substrate 120 may be reduced, and reflectivity of the mirror display may be increased.

### Modified Example 4

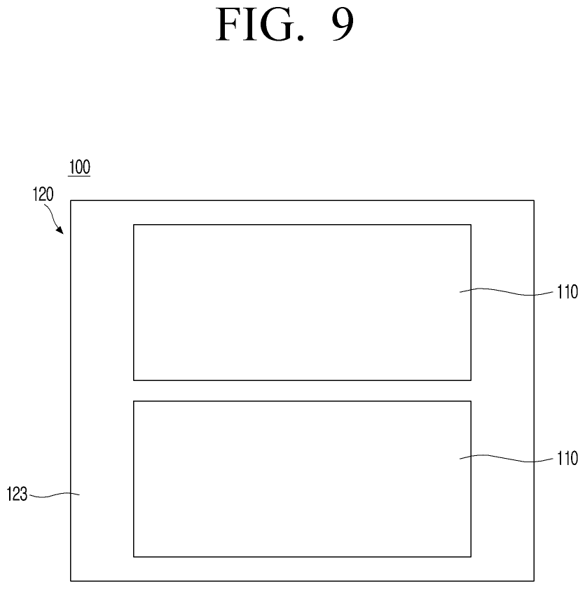

According to an example embodiment, multiple sheets of the display substrate may be joined to one sheet of the reflective substrate. FIG. 9 is a diagram showing a schematic configuration of the display apparatus 100 according to Modified Example 4, and shows the display apparatus 100 viewed from a rear side of the display apparatus 100. As shown in FIG. 9, in the display apparatus 100 according to Modified Example 4, two small display substrates 110 may be joined to a large reflective substrate 120. In addition, a region (or non-overlapping region) of the reflective substrate 120 to which the display substrate 110 is not joined may be covered by the second light-shielding layer 123.

Hereinabove, the display apparatus according to the present disclosure is described with reference to various example embodiments. However, elements of the display apparatus according to the present disclosure may be appropriately added, modified, replaced, and/or omitted by those skilled in the art within the scope of the present disclosure.

For example, the above-described example embodiments describe that the reflective substrate 120 may be larger than the display substrate 110 as an example. However, the reflective substrate 120 is not necessarily larger than the display substrate 110, and for example, the reflective substrate 120 and the display substrate 110 may have substantially the same size as each other. In this case, for example, the dummy aperture 122HD may be disposed at an edge area of the reflective substrate 120.

The above-described example embodiments (e.g., the example embodiments of FIGS. 1-4 and Modified Examples 1-4) describe that a size of the aperture 122H disposed in the reflective layer 122 may be larger than a size of the light-emitting element 112 (e.g., front surface of the light-emitting element 112) as an example. However, the size of the aperture 122H is not limited to being larger than the size of the light-emitting element 112. For example, the size of the aperture 122H may be the same as the size of the front surface of the light-emitting element 112, or may be smaller than the size of the front surface of the light-emitting element 112. In addition, a shape of the aperture 122H is not particularly limited, and may be appropriately changed based on a shape of the front surface of the light-emitting element 112.

In the above-described example embodiments, it is described that the first light-shielding layer 113 may be disposed on the display substrate 110. However, the first light-shielding layer 113 may be disposed on the reflective substrate 120. For example, the first light-shielding layer 113 may be disposed by being stacked on a surface of the reflective layer 122 that is adjacent to the display substrate 110. In this case, the light-emitting element 112 may be mounted on the circuit board 111 by the known bonding technique such as soldering. The first light-shielding layer 113 may include, for example but not limited to, the black matrix material.

The above-described example embodiments describe the light-emitting element 112 as an inorganic light-emitting element (or the micro LED). However, the light-emitting element 112 is not limited to the inorganic light-emitting element, and may use various light-emitting elements such as an organic light-emitting element.

In the above-described example embodiments, the reflective layer 122 may be disposed on the surface (e.g., rear surface) of the transparent substrate 121 that faces the display substrate 110. However, the reflective layer 122 may be disposed on a surface (e.g., front surface) of the transparent substrate 121, which is opposite to the surface facing the display substrate 110. In this case, an anti-oxidation film may be disposed on the reflective layer 122.

In the above-described example embodiments, it is described that the non-display region R2, in which the dummy aperture 122HD is disposed, may be disposed outside the display region R1, in which the aperture 122HR for transmitting light emitted from the light-emitting element 122 therethrough is disposed. However, a positional relationship between the display region R1 and the non-display region R2 is not limited to this example in which the non-display region R2 is disposed outside the display region R1. It is sufficient if the display region R1 and the non-display region R2 are different regions, and for example, the non-display region R2 may be disposed inside the display region R1.

The above-described example embodiments describe the display apparatus in the present disclosure as an example of the mirror display. However, the display apparatus in the present disclosure is not limited to the mirror display, and may be any other types of a display, for example, a decoration display (or decoration panel). In this case, instead of the reflective layer defining the aperture, for example, a decoration layer (or decoration film) may be disposed on the transparent substrate included in the aperture substrate. In addition, the aperture substrate may not be the transparent substrate, and may be a configuration in which a through hole is formed in a non-transparent substrate.

While the present disclosure has been particularly shown and described with reference to example embodiments thereof, it will be understood that various changes in form and details may be made therein without departing from the spirit and scope of the following claims

What is claimed is:

1. A display apparatus comprising:
a display substrate on which a plurality of light-emitting elements are arranged; and
an aperture substrate facing the display substrate, and including:
a display region in which at least one aperture is disposed at each position corresponding to each of the plurality of light-emitting elements and a light emitted from each of the plurality of light-emitting elements is transmitted through the at least one aperture; and
a non-display region which is different from the display region and in which at least one dummy aperture is disposed.

2. The display apparatus as claimed in claim 1, wherein the aperture substrate includes:
a transparent substrate; and
a reflective layer which is disposed on the transparent substrate and in which the at least one aperture is disposed.

3. The display apparatus as claimed in claim 1, wherein the aperture substrate is larger than the display substrate,
wherein the at least one dummy aperture is disposed in a non-overlapping region of the aperture substrate that does not overlap with the display substrate, and
wherein the aperture substrate further includes a light-shielding layer disposed on a surface of the display substrate in the non-overlapping region.

4. The display apparatus as claimed in claim 3, wherein the display substrate includes a plurality of display substrates, and
wherein the plurality of display substrates are joined to one aperture substrate.

5. The display apparatus as claimed in claim 1, wherein, in the non-display region, a dummy light-emitting element is disposed at a position corresponding to the at least one dummy aperture.

6. The display apparatus as claimed in claim 1, wherein the display substrate includes:
a circuit board; and
the plurality of light-emitting elements disposed on the circuit board.

7. The display apparatus as claimed in claim 6, wherein the display substrate further includes a light-shielding layer that is disposed in a region on the circuit board other than a region in which a light-emitting element is disposed on the circuit board.

8. The display apparatus as claimed in claim 7, wherein the light-shielding layer included in the display substrate covers a side surface of the light-emitting element.

9. The display apparatus as claimed in claim 1, further comprising a transparent adhesive layer disposed between the display substrate and the aperture substrate.

10. The display apparatus as claimed in claim 1, wherein the plurality of light-emitting elements include a micro light-emitting diode (LED).

11. The display apparatus as claimed in claim 1, wherein a size of an aperture of the at least one aperture is the same as or larger than a size of a light-emitting element of the plurality of light-emitting elements.

12. The display apparatus as claimed in claim 1, wherein in the display region, one aperture is disposed to correspond to one light-emitting element.

13. The display apparatus as claimed in claim 1, wherein in the display region, one aperture is disposed to correspond to a predetermined number of light-emitting elements among the plurality of light-emitting elements.

14. The display apparatus as claimed in claim 1, wherein the plurality of light-emitting elements include a blue light-emitting element, a green light-emitting element, and a red light-emitting element.

15. The display apparatus as claimed in claim 1, wherein the plurality of light-emitting elements include light-emitting elements that emit a light of a specific wavelength, and
wherein the display apparatus further comprises a color conversion layer that converts the light of the specific wavelength into a light of a different wavelength.
